(19) United States
(12) Patent Application Publication
(10) Pub. No.: US 2024/0194256 A1
(43) Pub. Date: Jun. 13, 2024

(54) WORD LINE DRIVERS FOR MEMORY DEVICES

(71) Applicant: Micron Technology, Inc., Boise, ID (US)

(72) Inventors: Brenton P. Van Leeuwen, Boise, ID (US); Mingdong Cui, Folsom, CA (US); Fatma Arzum Simsek-Ege, Boise, ID (US)

(21) Appl. No.: 18/373,490

(22) Filed: Sep. 27, 2023

Related U.S. Application Data
(60) Provisional application No. 63/431,870, filed on Dec. 12, 2022.

(51) Int. Cl. G11C 13/00

(52) U.S. Cl. CPC G11C 13/0028; G11C 13/0038

(57) ABSTRACT

Systems, methods and apparatus are provided for word line drivers for memory devices. For instance, an apparatus can include sets of word lines, each word line of the sets of word lines configured to access a respective set of one or more memory cells, sets of digit lines, where each word line couples a memory cell of the set of one or more memory cells with each digit line within the sets of digit lines, and a plurality of resistors coupled to the sets of word lines.

### PRIORITY INFORMATION

This application claims the benefit of U.S. Provisional Application No. 63/431,870 filed on Dec. 12, 2022, the contents of which are incorporated herein by reference.

### TECHNICAL FIELD

The present disclosure relates generally to memory devices, and more particularly, to word line drivers in memory devices.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

As designs shrink, less semiconductor space is available for circuitry that supports the function of memory, such as DRAM arrays. A respective memory cell for DRAM may include an access device, e.g., transistor, having a first and a second source/drain regions separated by a channel region. A gate may oppose the channel region and be separated therefrom by a gate dielectric. An access line, such as a word line, is electrically connected to the gate of the transistor. A DRAM cell can include a storage node, such as a capacitor cell, coupled by the access device to a digit line. The access device can be activated (e.g., to select the cell) by an access line coupled to the access transistor. The capacitor can store a charge corresponding to a data value of a respective cell (e.g., a logic “1” or “0”).

### BRIEF DESCRIPTION OF THE DRAWINGS

FIG. 1 is a schematic illustration of a material arrangement that support sub word-line driver circuits for memory devices in accordance with a number of embodiments of the present disclosure.

FIG. 2 is a schematic illustration of a memory that supports sub word-line driver circuits for memory devices in accordance with a number of embodiments of the present disclosure.

FIG. 3 is a schematic illustration of a memory that supports sub word-line driver circuits for memory devices in accordance with a number of embodiments of the present disclosure.

FIG. 4 is a flow diagram representing an example method that supports sub word-line driver circuits for memory devices in accordance with a number of embodiments of the present disclosure.

FIG. 5 is a flow diagram representing an example method that supports sub word-line driver circuits for memory devices in accordance with a number of embodiments of the present disclosure.

### DETAILED DESCRIPTION

Embodiments of the present disclosure describe a sub word-line driver for semiconductor devices. Memory devices may include various arrangements of memory cells and supporting circuitry formed over a substrate, such as a semiconductor substrate (e.g., a wafer of crystalline semiconductor, such as crystalline silicon). For example, a memory device may include one or more decks of memory cells over a substrate (e.g., of a memory die), where a deck may refer to a plane or level of memory cells above and parallel to the substrate. The one or more decks of memory cells may be associated with various arrangements of access line conductors, including access line conductors extending along one or more directions over a substrate, access line conductors along a direction from a substrate, or various combinations thereof. In some examples, circuitry for accessing the memory cells of a memory device (e.g., circuitry for selecting, accessing, or biasing access line conductors), such as driver circuitry, decoder circuitry, and other circuitry of the memory device may include transistors that are formed at least in part from doped portions of a substrate of a memory die (e.g., substrate-based transistors, transistors having channels formed from doped crystalline silicon or another semiconductor). However, as memory devices scale with a greater quantity of memory cells, (e.g., a greater density of memory cells over a memory die substrate, a greater quantity of layers or decks of memory cells above a memory die substrate), the area of a substrate of a memory die for circuitry to access the memory cells may decrease, which may lead to various limitations (e.g., related to the limited area of a substrate to support a growing quantity of memory cells and, by extension, a growing quantity and area for such substrate-based circuitry).

In accordance with examples as disclosed herein, a memory device may include a first semiconductor die (e.g., including a first semiconductor substrate, a first memory die) associated with at least memory cells and corresponding access lines of the memory device, and a second semiconductor die (e.g., including a second semiconductor substrate, a second memory die) associated with at least access line driver circuitry of the memory device. The memory device may include various configurations of electrical contacts, formed in contact with at least a portion of the second semiconductor die and in contact with at least a portion of the first semiconductor die, that electrically couple the access line driver circuitry of the second semiconductor die with the access lines of the first semiconductor die. For example, the second semiconductor die may be located (e.g., placed, fixtured, attached, bonded) in contact with or otherwise adjacent to the first semiconductor die, and cavities may be formed through at least the second semiconductor die (e.g., through at least the substrate of the second semiconductor die) and at least expose a portion of the first semiconductor die. In some examples, such cavities may be coincident with respective conductors (e.g., landing pads, contact patches) of the second semiconductor die that are coupled with the access line drivers, and coincident with respective conductors of the first semiconductor die that are coupled with the access line conductors. The electrical contacts between the second semiconductor die and the first semiconductor die may be formed at least in part from forming (e.g., depositing) a conductive material in the cavities. In some other examples, electrical coupling between access line driver circuitry of the second semiconductor die and access lines of the first semiconductor die may additionally, or alternatively, be supported by other techniques, such as an electrical coupling between respective contacts of (e.g., at the surface of) the second semiconductor die, or the first semiconductor die, or both.

In order to maximize the space used by the access line driver circuitry in the second semiconductor die, access line driver circuitry with a single NMOS transistor may be utilized. As such, with the embodiments described herein, access line driver circuitry is able to be confined in a 200 nanometer by 580 nanometer area of the second semiconductor die, maximizing the efficiency of the design, as compared to access line driver circuit that need a larger amount of space. For example, such techniques may increase the amount of space in the semiconductor die for other circuitry such as sensing circuitry, decoding circuitry, or periphery circuitry, among other circuitry used for accessing or otherwise operating memory cells of a memory device, which may be implemented on the first semiconductor die, or the second semiconductor die, or various combinations thereof. In some examples, implementing such circuitry in the substrate-based circuitry of a memory device may alleviate or mitigate area utilization challenges or routing challenges, which may improve scaling in memory devices by supporting a greater quantity of memory cells (e.g., a greater quantity of decks) for a given footprint, among other advantages.

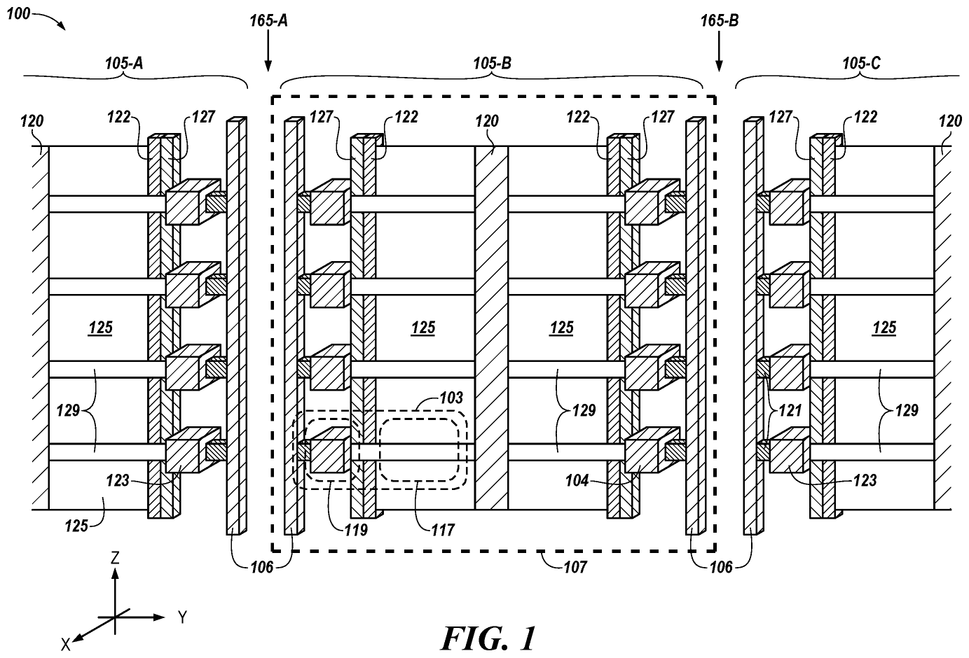

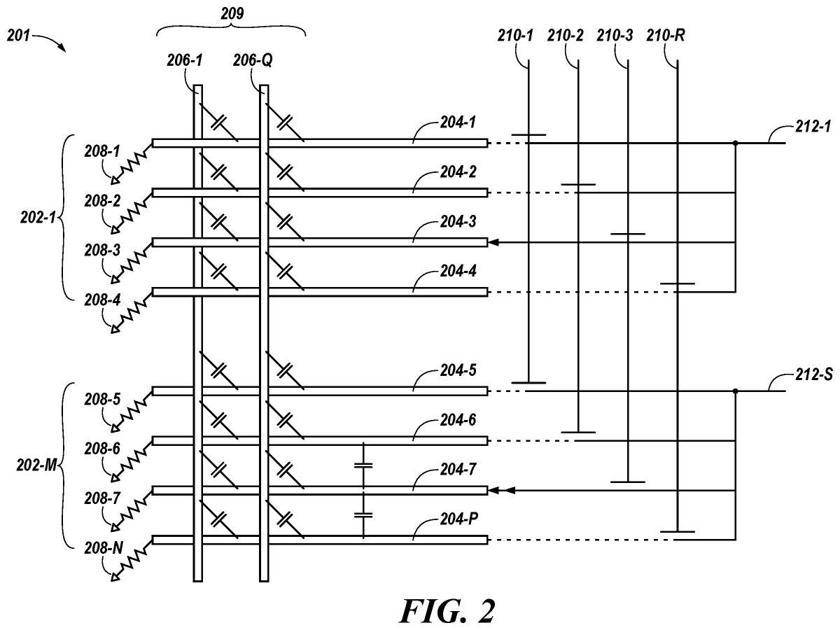

The figures herein follow a numbering convention in which the first digit or digits correspond to the figure number of the drawing and the remaining digits identify an element or component in the drawing. Similar elements or components between different figures may be identified by the use of similar digits. For example, reference numeral 104 may reference element “04” in FIG. 1, and a similar element may be referenced as 204 in FIG. 2. Multiple analogous elements within one figure may be referenced with a reference numeral followed by a hyphen and another numeral or a letter. For example, 304-1 may reference element 304-1 in FIGS. 3 and 304-2 may reference element 304-2, which may be analogous to element 304-1. Such analogous elements may be generally referenced without the hyphen and extra numeral or letter. For example, elements 304-1 and 304-2 or other analogous elements may be generally referenced as 304.

FIG. 1 is a schematic illustration of a material arrangement that support sub word-line drivers for memory devices in accordance with a number of embodiments of the present disclosure. For example, FIG. 1 illustrates a cross-section of a portion of the material arrangement 100 in an yz-plane. FIG. 1 may illustrate aspects of operations for fabricating aspects of a material arrangement 100, which may illustrate one or more arrangements of materials over a substrate (e.g., a semiconductor substrate, a semiconductor wafer, a crystalline semiconductor, a substrate of a semiconductor die, a substrate of a memory die). The material arrangement 100 may be described with reference to an x-direction (e.g., a direction over the substrate, such as parallel to the substrate), a y-direction (e.g., another direction over the substrate, such as parallel to the substrate, which may be perpendicular or otherwise skewed relative to the x-direction), and a z-direction (e.g., a direction away from the substrate, such as a height direction or a thickness direction relative to the substrate, which may be perpendicular to an xy-plane or skewed relative to a direction perpendicular to an xy-plane), as illustrated. Although the material arrangement 100 illustrate examples of some relative dimensions and quantities of various features, aspects of each respective material arrangement may be implemented with other relative dimensions or quantities of such features in accordance with examples as described herein. In some cases, a view of a material arrangement may show structures that are beneath other structures. By making some upper layers transparent, some details may be viewed, which may illustrate examples of relative positions of elements and features.

Operations illustrated in and described with reference to FIG. 1 may be performed by a manufacturing system, such as a semiconductor fabrication system configured to perform additive operations (e.g., depositing, epitaxy, bonding), subtractive operations (e.g., etching, trenching, planarizing, polishing), modifying operations (e.g., oxidizing, doping, reacting, converting), and supporting operations (e.g., masking, patterning, photolithography, aligning, bonding), among other operations of formation that support the described techniques. In some cases, operations performed by such a manufacturing system may be supported by a process controller or its components as described herein.

The material arrangement 100 illustrates an example of features that may be formed in a first semiconductor die (e.g., including an array of memory cells 103 and associated access line conductors), at least a portion of which may be formed separately from a second semiconductor die that includes access line driver circuitry operable to bias access line conductors of the first semiconductor die.

Aspects of the material arrangement 100 may be described with reference to regions 105. Each region 105 may include a respective memory array. Each memory array may include a three-dimensional array of memory cells 103, and each memory cell 103 may include a respective capacitor 117 (e.g., a capacitance between electrical nodes that is supported by formed material portions) and a respective switching component 119 (e.g., switching component 119, a material portion operable to couple the capacitor 117 with digit lines). Each region 105 also may include a set of word lines (e.g., a vertical stack of word line 104) and a set of digit lines.

Each region 105 may also include a plate conductor 120, which may be an example of a plate node of the material arrangement 100 that is coupled with a plate voltage source. In the example of material arrangement 100, each word line 104 may extend along the x-direction, and a set of word lines (e.g., a vertical stack of word lines 104) may be arranged along the z-direction, such that each word line 104 of a set of word lines is associated with a location and an extent (e.g., a thickness) along the z-direction. The example of material arrangement 100 illustrates an example in which each region 105 includes a set of word lines on both sides (e.g., along the y-direction) of a plate conductor 120 but, in some other examples, a material arrangement in accordance with the disclosed techniques may include a set of word lines on a single side of a plate conductor 120, among other configurations. In the example of material arrangement 100, each digit line 106 may extend along the z-direction, and a set of digit line (e.g., digit lines 106) may be arranged along the x-direction. Each word line 104 may be operable to couple a respective capacitor 117 with each digit line 106 of a set of digit line (e.g., digit lines 106) along the x-direction.

The regions 105 may be separated from one another by isolation regions 165 (e.g., a trench, a trench isolation region), which may include one or more dielectric materials (not shown) that support an electrical isolation between at least portions of the regions 105. In the example of the material arrangement 100, the regions 105-a and 105-c may include features similar or identical to the region 105-b, but are truncated for illustrative purposes. In some cases, one or more isolation regions 165 (e.g., an isolation region 165-a and an isolation region 165-b) may extend along the z-direction, but other isolation regions may extend along other directions, such as around a perimeter of a region 105 or at least partially enclosing a volume of a region 105.

The material arrangement 100 may be an example of a portion of a semiconductor die after a set of one or more manufacturing operations. For example, forming the material arrangement 100 may include forming a stack (e.g., extending along the z-direction) of (e.g., including) alternating layers of a material 125 and a semiconductor material 129 (e.g., silicon, epitaxial silicon). In some examples, the material 125 as illustrated may be a sacrificial material (e.g., silicon germanium), which may be deposited or otherwise formed in layers with (e.g., between) layers of the semiconductor material 129, and which may be removed (e.g., exhumed) in a later operation and replaced with another material, such as a dielectric material (e.g., silicon nitride) to provide an electrical isolation (e.g., along the z-direction, between layers of the semiconductor material 129). In some other examples, the material 125 as illustrated may be a dielectric material (e.g., silicon nitride) which, in various examples, may be deposited or otherwise in layers with (e.g., between) layers of the semiconductor material 129, or may be illustrative of a material that replaced a sacrificial material (e.g., after a removal of the sacrificial material, such as in an exhume operation) that was formed (e.g., deposited, oxidized) between layers of the semiconductor material 129.

In some cases, forming the material arrangement 100 may be supported by forming a stack of alternating layers (e.g., alternating layers of the semiconductor material 129 and the material 125, or a material that may be removed to form voids in which the material 125 may be formed) over a substrate (e.g., a semiconductor wafer, a substrate of crystalline semiconductor, not shown). For illustrative purposes, a stack of alternating layers supporting the formation of the material arrangement 100, may include five layers of the material 125 and four layers of the semiconductor material 129. However, a stack of alternating layers may include any quantity of layers of the material 125 and any quantity of layers of the semiconductor material 129.

Forming the material arrangement 100 may also include forming one or more trenches through the stack of alternating layers. As described herein, a trench may refer to a region formed by a subtractive operation (e.g., a dry etch operation, a wet etch operation) where one or more materials (e.g., material layers) are removed along the z-direction via an opening that may be elongated along one or more directions in an xy-plane (e.g., along the x-direction, along the y-direction, along other directions or combinations of directions, at an exposed surface of the semiconductor die), which may include trenching around a perimeter of a portion of a material arrangement. For example, the first manufacturing operation may include forming a stack of alternating layers that is continuous through the region 105-a, the region 105-b, and the region 105-c. Two trenches may be formed such that the stack of alternating layers is separated between the region 105-a, the region 105-b, and the region 105-c. In some cases, forming the material arrangement 100 may include forming (e.g., depositing) a layer of a masking material (e.g., a hard mask, not shown) over the stack of alternating layers. The layer of the masking material may be formed over the stack of alternating layers (e.g., over a top layer of the material 125, over a top layer of the semiconductor material 129), and may support various photolithography operations (e.g., patterning openings for trenches or other cavities).

In some cases, forming the material arrangement 100 may include forming voids (e.g., recesses) between one or more layers of the material 125, between one or more layers of the semiconductor material 129, or both. In some examples, forming a void (e.g., forming a recess, exhuming) may refer at least in part to removing one or more materials (e.g., sacrificial materials) between layers of material that are not removed, which may include a material removal along a direction in an xy-plane. For example, a trench may be used to access and form a void between layers of the semiconductor material 129 (e.g., a void in one or more layers of a sacrificial material, via an exposed sidewall of the sacrificial material). In some cases, a void may be formed by an etching operation (e.g., a wet etch operation), which may expose sidewalls of a material (e.g., the material 125). In some examples, the etching operation may expose surfaces of a material (e.g., the material 125) in an xz-plane, in an yz-plane, or a combination thereof. In some examples, an etching operation may remove one or more portions of a sacrificial material. For example, the etching operation may offset, along the x-direction, along the y-direction, or both, portions of (e.g., sidewalls of) one or more layers of the sacrificial material.

In some examples, forming the material arrangement 100 may include forming a dielectric material 122 (e.g., a film of an inter-tier dielectric (ITD)), which may include a formation at least on sidewalls of the material 125. The dielectric material 122 may be formed (e.g., deposited) on exposed sidewalls (e.g., sidewalls in at least an xz-plane) of one or more layers of the material 125. Although the material arrangement 100 illustrates an example in which each layer of the semiconductor material 129 intersects the dielectric material 122, in some other examples, one or more layers of the semiconductor material 129 may not intersect the dielectric material 122, or the dielectric material 122 may be formed in another configuration or omitted. In some cases, the dielectric material 122 may be silicon nitride.

Additionally, or alternatively, forming the material arrangement 100 may also include forming layers of a gate oxide material 127. In some examples, the gate oxide material 127 may be formed on sidewalls of the layers of the dielectric material 122. Layers of the gate oxide material 127 may extend along directions in an xz-plane and may be formed (e.g., deposited) on one or more extents (e.g., along the y-direction) of a respective layer of the dielectric material 122. For example, the region 105-b may include two layers of the gate oxide material 127. Although the material arrangement 100 illustrates an example in which each layer of the semiconductor material 129 intersects the gate oxide material 127, in some other examples, one or more layers of the semiconductor material 129 may not intersect the gate oxide material 127, or the gate oxide material 127 may be formed in another configuration or omitted. In some cases, the gate oxide material 127 may be germanium oxide.

Forming the material arrangement 100 may also include forming word lines 104 using a conductive material 123. The word lines 104 may extend along the x-direction. In some cases, the word lines 104 may be formed to bypass or surround (e.g., enclose, in an xz-plane) around the semiconductor material 129. In some examples, the portion of the word lines 104 that bypasses or surrounds a portion of the semiconductor material 129 may support a gate portion of a switching component 119, and the portion of the semiconductor material 129 may support a channel portion of the switching component 119. In some examples, the portion of the word lines 104 may be separated from the portion of the semiconductor material 129 by a gate oxide material, which may be the same as the gate oxide material 127 (e.g., germanium oxide), may be a different material than the gate oxide material 127, or may be implemented in the absence of the gate oxide material 127. In some cases, the conductive material 123 may be titanium nitride.

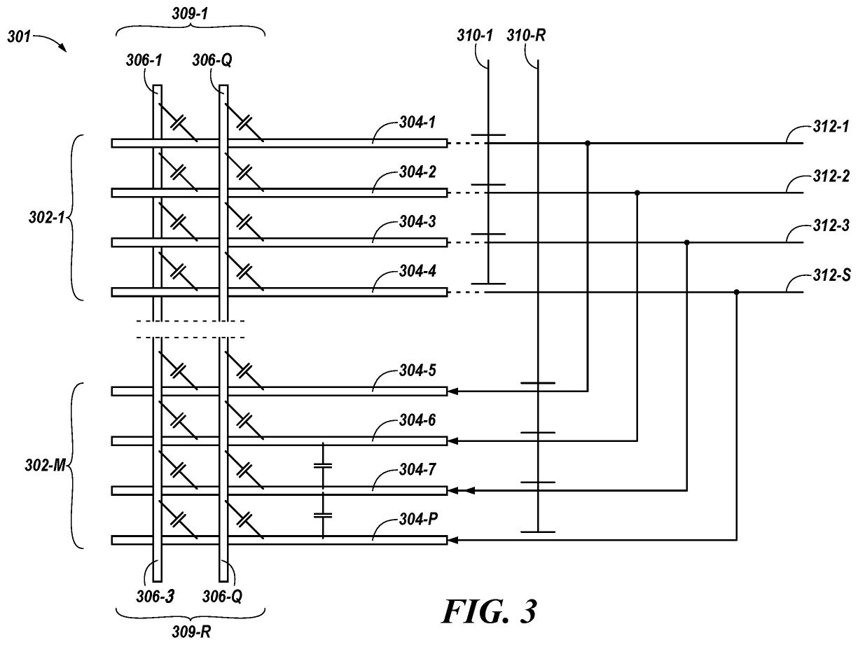

Forming the material arrangement 100 may also include forming a set of digit lines (e.g., digit lines 106) and one or more plate conductors 120 using the conductive material 123. The digit lines 106 may extend along the z-direction. In some embodiments, the digit lines 106 may be formed to connect to another digit line at the bottom of the stacked set of word lines 104. That is, as illustrated in FIG. 2, the digit lines 106 can be a continuous digit lines 106 that extends between each stacked set of word lines 104. However, this disclosure is not so limited. For instance, the digit lines 106 may be formed to disconnect, at the bottom of the stacked set of word lines 104, from another digit line coupled to another stacked set of word lines. That is, as illustrated in FIG. 3, the digit lines 106 may not form continuous digit lines 106 and may end at the bottom of the stacked set of word lines 104.

In some examples, the set of digit line (e.g., digit lines 106) may be coupled (e.g., physically, electrically) between respective doped regions 121 (e.g., of the semiconductor material 129), in which case the respective doped regions 121 also may support a channel portion of a respective switching component 119. The plate conductors 120 may extend along the z-direction and may be electrically coupled with respective layers of semiconductor material 129. In some cases, forming plate conductors 120 may occur prior forming the stack of alternating layers of the material 125 and the semiconductor material 129. In some other cases, forming plate conductors 120 may occur after forming the stack of alternating layers of the material 125 and the semiconductor material 129 (e.g., by forming a trench through the stack and depositing the conductive material 123 in the trench).

The material arrangement 100 also may include one or more capacitors 117, which may support storing a charge corresponding to a stored logic state of the memory cell 103. In some cases, each capacitor 117 of a two-dimensional set (e.g., in an xz-plane) may be coupled with a same plate conductor 120, and a plate conductor 120 may be coupled between two of such two-dimensional sets of capacitors 117. The capacitors 117 may each be operable to couple with a digit line 106 of the set of digit line (e.g., digit lines 106) based on a voltage applied to a respective switching component 119 via a word line 104. In some examples, the capacitors 117 may utilize an intrinsic capacitance of the semiconductor material 129 between a respective switching component 119 and a respective plate conductor 120. In some other examples, a capacitor 117 may be supported by one or more other materials, not shown, that otherwise support such a capacitance or a polarization (e.g., utilizing a ferroelectric material as part of a capacitor 117).

Although not shown in FIG. 1, each word line 104 of a set of word lines (e.g., along the z-direction) may have a different extent (e.g., length, along the x-direction). That is, respective portion of sets of word lines (e.g., vertically stacked set of word lines 104), may have a different extent along the x-direction.

FIG. 2 is a schematic illustration 201 of a memory that supports sub word-line driver circuits for memory devices in accordance with a number of embodiments of the present disclosure. FIG. 2 illustrates a circuit diagram showing a sub word-line driver circuit of a memory device according to an embodiment of the present disclosure. FIG. 2 illustrates sub word-line driver circuitry that may drive sets of word lines 202 (individually referring to first set of word lines 202-1 and second set of word lines 202-M), the sets of word lines 202 may be configured to access a respective set of one or more memory cells in the memory device. That is, each set of word lines 202 may be made up of a plurality of word lines 204 (individually referring to word line 204-1, 204-2, 204-3, 204-4, 204-5, 204-6, 204-7, 204-P).

For example, a first set of word lines 202-1 may include a first plurality of word lines 204-1, 204-2, 204-3, 204-4. Similarly, a second set of word lines 202-M may include a second plurality of word lines 204-5, 204-6, 204-7, 204-P. The set of word lines 202 may be vertically stacked sets of word lines 202. In some embodiments, the array circuitry may include sets of digit lines 209. Each digit line 206-1, 206-Q of the set of digit lines 209 may be coupled (e.g., physically, electrically) to memory cells controlled by each word line 204 in the set of word lines 202. Further, each word line 204 can couple a memory cell with each digit line 206 within the sets of digit lines 209.

Each word line 204 in the sets of word lines 202 may be coupled to a resistor 208 (individually referring to resistor 208-1, 208-2, 208-3, 208-4, 208-5, 208-6, 208-7, 208-N). For example, resistor 208-1 may be coupled to word line 204-1, resistor 208-2 may be coupled to word line 204-2, . . . resistor 208-7 may be coupled to word line 204-7, and resistor 208-N may be coupled to word line 204-P. The resistors may have a resistance in a range from 100 megaohms (MΩ) to 1 gigaohm (GΩ).

In some embodiments, the resistors 208 may assist with word line 204 coupling and drifting. For instance, when a particular word line (e.g., word line 204-7) is activated, word lines (e.g., word lines 204-6, 204-P) adjacent to the activated word line may unintentionally increase in voltage. The resistors 208 coupled to the word lines 204 can counter act the unintentional increase in voltage to the adjacent word lines by decreasing the voltage of the adjacent word lines (e.g., word lines 204-6, 204-P), to ensure that only the specified word line (e.g., word line 204-7) is activated. In some embodiments, the activated word line (e.g., word line 204-7) would have to overcome the resistor (e.g., resistor 208-7) counter acting the activation of the specified word line (e.g., word line 204-7). That is, the activated word line (e.g., word line 204-7) may use more energy to reach the designated voltage for activation. Using resistors 208 to counter act the increased voltage of adjacent word lines (e.g., word 204-6, 204-P) may limit drifting and coupling of adjacent word lines (e.g., word lines, 204-6, 204-P).

The sub word-line driver circuit may include phase drivers 210 (individually referring to phase driver 210-1, 210-2, 210-3, 210-R) and word line drivers 212 (individually referring to word line driver 212-1, 212-S) to activate a particular word line (e.g., word line 204-7). In some embodiments, the sub word-line driver circuit may include a plurality of phase drivers 210 associated with each set of the word lines 204. A phase driver 210 can direct voltage to a word line 204-1, 204-2, 204-3, 204-4 from a first set of word lines 202-1 and another word line 204-5, 204-6, 204-7, 204-P in a second set of word lines 202-M. Specifically, each phase driver 210 may direct voltage to a particular word line 204 in each set of word lines 202. For example, phase driver 210-1 may direct voltage to word line 204-1 of the first set of word lines 202-1 and word line 204-5 of the second set of word lines 202-M, phase driver 210-2 may direct voltage to word line 204-2 of the first set of word lines 202-1 and word line 204-6 of the second set of word lines 202-M, phase driver 210-3 may direct voltage to word line 204-3 of the first set of word lines 202-1 and word line 204-7 of the second set of word lines 202-M, and phase driver 210-R may direct voltage to word line 204-4 of the first set of word lines 202-1 and word line 204-P of the second set of word lines 202-M.

The phase driver 210 may provide a positive voltage to the gate of the sub word-line driver ranging from 4 to 4.5 volts. For example, the phase driver 210-3 can provide a positive voltage of 4.2 volts to the gate of the sub word-line driver (e.g., single NMOS transistor) to activate the word line 204-7. That is, phase driver 210-3 can open word line 204-7 to word line driver 212-S to enable a positive voltage of 4.2 volts to reach word line 204-7. Similarly, phase driver 210-3 can open word line 204-3 to word line driver 212-1 to enable a negative voltage of −0.55 to reach word line 204-3. That is, phase driver 210 can provide a negative voltage to the gate of the sub word-line driver ranging from −0.6 to −0.05. In some embodiments, the resistors 208-6, 208-N may reduce the amount of voltage word lines 204-6, 204-P receive to prevent word line coupling. That is, the resistor 208-6, 208-N can bias the voltage received by adjacent word lines 204-6, 204-P (e.g., adjacent to activated word line 204-7) to a negative voltage (e.g., −0.55 volts) when word line 204-7 is activated.

In some embodiments, the sub word-line driver circuit may include a plurality word line driver 212 coupled to each set of word lines 202. Specifically, each word line driver 212 may be coupled to a particular set of word lines 202. For example, the first word line driver 212-1 may be coupled to the first set of word lines 202-1. Further, the first word line driver 212-1 may be coupled to word line 204-1, word line 204-2, word line 204-3, and word line 204-4 of the first set of word lines 202-1. In addition, the second word line driver 212-S may be coupled to the second set of word lines 202-M. The second word line driver 212-S may be coupled to word line 204-5, word line 204-6, word line 204-7, and word line 204-P of the second set of word lines 202-M. The first word line driver 212-1 may be used to activate the first plurality of word lines 204-1, 204-2, 204-3, 204-4 in the first set of word lines 202-1 and the second word line driver 212-S may be used to activate the second plurality of word lines 204-5, 204-6, 204-7, 204-P in the second set of word lines 202-S. That is, the word line drivers 212 may send a voltage to the word lines 204 to activate the word lines 204. For instance, when activating a word line 204, the word line drivers 212 may provide a voltage between −0.6 to 3.5 volts to the word line 204. For example, the word line driver 212-1 can provide a positive voltage of 3 volts and the word line driver 212-S can provide a negative voltage of −0.55 volts.

In some embodiments, the phase drivers 210 and the word line drivers 212 can send a voltage to word lines 204 in the set of word lines 202. For example, as illustrated in FIG. 2, the phase driver 210-3 can direct a positive voltage sent from the word line driver 212-S to word line 204-7 in the second set of word lines 202-M. The resistor 208-1, 208-2, 208-4, 208-5, 208-6, 208-N can bias the unselected word lines 204-1, 204-2, 204-4, 204-5, 204-6, 204-P to a negative voltage (−0.55 volts). Each unselected word line 204-1, 204-2, 204-4, 204-5, 204-6, 204-P may be floated during the activation of word line 204-7. Using the resistors 208 in this manner assist in reducing digit line/word line coupling and word line/word line coupling by maintaining a negative voltage for the unselected word lines.

FIG. 3 is a schematic illustration 301 of a memory that supports sub word-line driver circuits for memory devices in accordance with a number of embodiments of the present disclosure. FIG. 3 illustrates a circuit diagram showing a sub word-line driver circuit of a memory device according to an embodiment of the present disclosure. FIG. 3 illustrates sub word-line driver circuitry that may drive a first set of word lines 302-1, arranged in a vertical stack, and a second set of word lines 302-M, arranged in a vertical stack and communicatively coupled to the first set of word lines 302-1. In some embodiments, each set of word lines (e.g., first set of word lines 302-1, second set of word lines 302-M) may be configured to access a respective set of one or more memory cells in the memory device. That is, each set of word lines 302 may be made up of a plurality of word lines 304 (individually referring to word line 304-1, 304-2, 304-3, 304-4, 304-5, 304-6, 304-7, 304-P). For example, a first set of word lines 302-1 may include a first plurality of word lines 304-1, 304-2, 304-3, 304-3. Similarly, a second set of word lines 302-M may include a second plurality of word lines 304-5, 304-6, 304-7, 304-P. The set of word lines 302 may be vertically stacked sets of word lines 302.

The array circuitry may include a first set of digit lines 309-1 coupled to memory cells controlled by each word line 304-1, 304-2, 304-3, 304-4 in the first set of word lines 302-1 and a second set of digit lines 309-R coupled to memory cells controlled by each word line 304-5, 304-6, 304-7, 304-P in the second set of word lines 302-M. Each word line 304-1, 304-2, 304-3, 304-4 of the first set of word lines 302-1 can couple a memory cell of the set of one or more memory cells with each digit line 306-1, 306-2 in the first set of digit lines 309-1. Further, each word line 304-5, 304-6, 304-7, 304-P of the second set of word lines 302-M can couple a memory cell of the set of one or more memory cells with each digit line 306-3, 306-Q in the second set of digit lines 309-R.

In some embodiments, each set of digit lines 309 (individually referring to sets of digit lines 309-1, 304-R) may be physically and electrically separated (e.g., disconnected) from the other set of digit line 309. For example, the first set of digit lines 309-1 may be coupled to the first set of word lines 302-1 and the second set of digit lines 309-R may be coupled to the second set of word lines 302-M. The connection between the first set of digit lines 309-1 may be physically broken from the second set of digit lines 309-R. As such, there is no electric connectivity between the first set of digit lines 309-1 and the second set of digit lines 309-R. In addition, the first set of digit lines 309-1 may be physically and electrically disconnected from the second set of word lines 302-M. Similarly, the second set of digit lines 309-R may be physically and electrically disconnected from the first set of word lines 302-1.

In some embodiments, the connection between the first set of digit lines 309-1 and the second set of digit lines 309-R may be broken during the forming process. For example, the first set of digit lines 309-1 can be formed separately from the second set of digit lines 309-R to ensure there is no physical connection. In some embodiments, the disconnection between the first set of digit lines 309-1 and the second set of digit lines 309-R may occur through an etchant process (e.g., dry etch process), which eliminates the portion that physically connects the first set of digit lines 309-1 from the second set of digit lines 309-R.

The sub word-line driver circuit may include a plurality of phase drivers 310 (individually referring to phase driver 310-1, 310-R) and word line drivers 312 (individually referring to word line driver 312-1, 312-2, 312-3, 312-S) to activate word lines 304 in the set of word lines 302. In some embodiments, each phase driver 310 may direct voltage to a specified set of word lines 302. That is, a specified phase driver (e.g., first phase driver 310-1) may direct voltage to all the word lines (e.g., word lines 304-1, 304-2, 304-3, 304-4) in a set of word lines (e.g., first set of word lines 302-1) but may not be connected to or direct voltage to word lines (e.g., word lines 304-5, 304-6, 304-7, 304-P) in another set of word lines (e.g., second set of word lines 302-M). For example, the first phase driver 310-1 may direct voltage to the word lines 304-1, 304-2, 304-3, 304-4 in the first set of word lines 302-1. In addition, the second phase driver 310-R may direct voltage to the word lines 304-5, 304-6, 304-7, 304-P in the second set of word lines 302-M.

In some embodiments, the sub word-line driver circuit may include a plurality of word line drivers 312 coupled to word lines 304 from each set of word lines 302. For instance, each word line driver 312 may be coupled to a word line in the first set of word lines and a word line in the second set of word lines. For example, the first word line driver 312-1 may be coupled to word line 304-1 of the first set of word lines 302-1 and word line 304-5 of the second set of word lines 302-M, the second word line driver 312-2 may be coupled to word line 304-2 of the first set of word lines 302-1 and word line 304-6 of the second set of word lines 302-M, the third word line driver 312-3 may be coupled to word line 304-3 of the first set of word lines 302-1 and word line 304-7 of the second set of word lines 302-M, and the fourth word line driver 312-S may be coupled to word line 304-4 of the first set of word lines 302-1 and word line 304-P of the second set of word lines 302-M. The particular set up can reduce digit line/word line coupling and word line/word line coupling. For example, this set up allows for an activated word line (e.g., word line 304-7) to be in an “on position,” while allowing adjacent word lines (e.g., word line 304-6, 304-8) to be in an “off position.” Further, separating the set of digit lines 309 in a set of word lines (e.g., set of word line 302-1) from the digit lines in another set of word lines (e.g., set of word line 302-M), can prevent word line/digit line coupling in the set of word lines 302 that does not have an activated word line 304.

In some embodiments, when activating a particular word line (e.g., word line 304-7), in a set of word lines (e.g., second set of word lines 302-M), the word lines (e.g., 304-5, 304-6, 304-P) in the set of word lines (e.g., second set of word lines 302-M) may receive a negative voltage, while the particular word line (e.g., word line 304-7) receives a positive voltage. For example, the phase driver 310-R can direct a positive voltage from word line driver 312-3 to the activated word line 304-7 and direct negative voltages from word line drives 312-1, 312-2, 312-S to unselected word lines 304-5, 304-6, 304-P. Moreover, word lines (e.g., 304-1, 304-2, 304-3, 304-4) in another set of word lines (e.g., first set of word lines 302-1) may be floated during the activation of the particular word line (e.g., word line 304-7).

For example, the second phase driver 310-R and the third word line drive 312-3 can cause a voltage to be sent to the particular word line (e.g., 304-7), in the second set of word lines 302-M, to activate the particular word line (e.g., 304-7). In addition, the first word line driver 312-1, the second word line driver 312-2, and the fourth word line driver 312-S can send a negative voltage to the fifth word line 304-5, the sixth word line 304-6, and the eighth word line 304-P, respectively (e.g., the unselected word lines in the second set of word lines 302-M) That is, the unselected word lines 304-5, 304-6, 304-P not receiving a positive voltage in the second set of word lines 302-M will receive a negative voltage directed by the second phase driver 310-R, associated with the second set of word lines 302-M, from the respective word line drivers 312-1, 312-2, 312-S.

When activating a word line, the phase driver 310 may provide a positive voltage to the gate of the sub word-line driver ranging from 4 to 4.5 volts and a negative voltage to the gate of the sub word-line driver ranging from −0.6 to −0.05 volts. In addition, the word line drivers 312 may provide a voltage between −0.6 to 3.0 volts. For example, the phase driver 310-R can provide a positive voltage of 4.2 volts to the gate of the sub word-line driver and the phase driver 310-1 can provide a negative voltage of −0.55 volts to the gate of the sub word-line driver. Further, the word line driver 312 can provide a positive voltage of 3 volts and a negative voltage of −0.55 volts. For example, the word line driver 312-3 can provide a positive voltage of 3 volts and the word line drivers 312-1, 312-2, 312-S can provide a negative voltage of −0.55 volts.

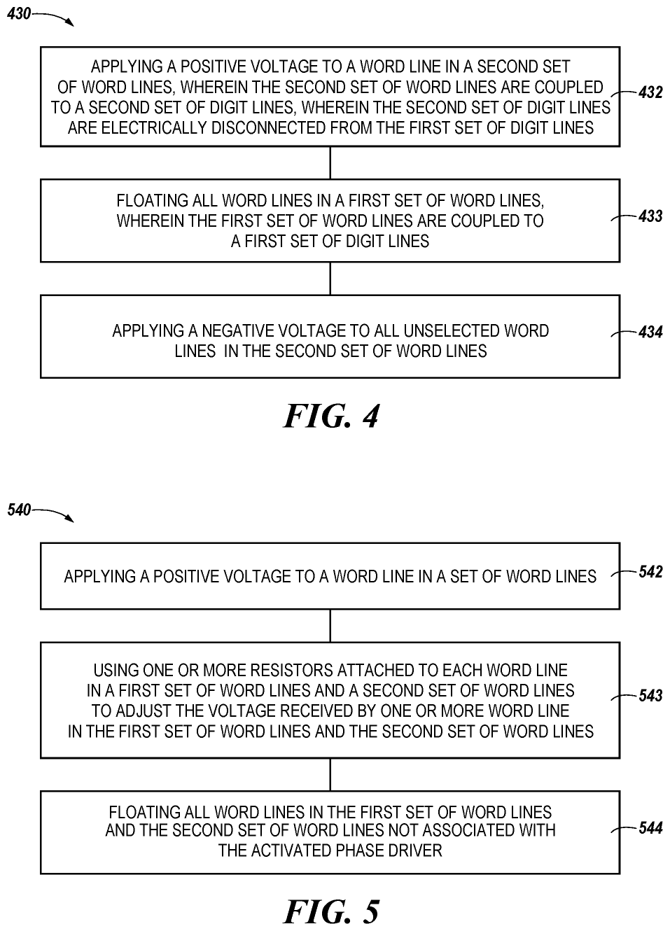

FIG. 4 is a flow diagram representing an example method 430 that supports sub word-line driver circuit for memory devices in accordance with a number of embodiments of the present disclosure. At 432, the method 430 includes applying a positive voltage to a word line in the second set of word lines. In some embodiments, the second set of word lines are coupled to a second set of digit lines. The second set of digit lines can be electrically disconnected from the first set of digit lines which are coupled to the first set of word lines. In some embodiments, the first phase driver may direct voltage to the first set of word lines, while the second phase driver may direct voltage to the second set of word lines, via the gate of the sub word-line drivers. In some embodiments, the second phase driver may be used to direct the positive voltage to the gate of the sub word-line drivers (e.g., single NMOS transistors) coupled to the second set of word lines. When the second phase driver directs a positive voltage to a word line in the second set of word lines, the first phase driver does not direct a voltage to the word lines in the first set of word lines. In addition, when the voltage is sent to the word line in the second set of word lines, the word lines in the first set of word lines may be floated.

In some embodiments, the sub word-line driver circuit may include a first word line driver, a second word line driver, a third word line driver, and a fourth word line driver. The first word line driver, the second word line driver, the third word line driver, and the fourth word line driver may be coupled to the first set of word lines and the second set of word lines. That is, each word line driver is coupled to a word line in each set of word lines. A word line driver coupled to a word line in a first set of word lines will also be coupled to the corresponding word line in the second set of word lines. For instance, as illustrated in FIG. 3, each word line driver is coupled to two word lines (e.g., a word line in the first set of word lines and a word line in the second set of word lines). The word line driver will activate one of the plurality of word lines coupled to the word line driver. For example, the third word line driver may be coupled to the third word line in the first set of word lines and the seventh word line in the second set of word lines. If the third word line driver sends a positive voltage to the seventh word line in the second set of word lines, the third word line in the first set of word lines will not receive a voltage and would rather be floated, as illustrated in FIG. 3. That is, the third word line driver may be used to apply the positive voltage to the word line in the second set of word lines.

At 433, the method 430 includes floating all word lines in a first set of word lines when the first set of word lines are coupled to the first set of digit lines. In some embodiments, when a word line in a second set of word lines is activated the word lines in the first set may be floated. That is, the word lines in the first set of word lines may be temporarily disconnected from the word line driver through the sub word-line driver. In some embodiments, separating the first set of digit line coupled to the first set of word lines from the second set of digit lines coupled to the second set of word lines can assist in floating the set of word lines. For instance, electrically separating the first set of digit lines coupled to the first set of word lines from the second set of digit lines coupled to the second set of word lines can allow for each set of word lines to be independently activated. When the first set of word lines are coupled to the first set of digit lines, the first set of word lines may not be coupled to the second set of digit lines. Said differently, the first set of word lines and the first set of digit lines may be electrically separated from the second set of digit lines. Similarly, the second set of word lines and the second set of digit lines may be electrically separated from the first set of digit lines. Electrically, separating the first set of word lines from the second set of digit lines when a word line in the second set of word lines is activated can help limit digit line/word line coupling.

At 434, the method 430 includes applying a negative voltage to all unselected word lines in the second set of word lines. In some embodiments, when a word line in a set of word lines receives a positive voltage the other word lines (e.g., unselected word lines) withing the set will receive a negative voltage. That is, the phase driver coupled to the sub word-line drivers associated with the set of word lines will direct a positive voltage to one sub word-line driver and a negative voltage to all other sub word-line driver in the set of word lines. Further, as described herein, each word line driver is coupled to a word line in each set of word lines. For example, the second word line driver may be coupled to the second word line in the first set of word lines and the sixth word line in the second set of word lines. Further, if the sixth word line in the second set of word lines receives a negative voltage, the second word line in the first set of word lines will not receive a voltage and would rather be floated, as illustrated in FIG. 3.

FIG. 5 is a flow diagram representing an example method that supports sub word-line driver circuits for memory devices in accordance with a number of embodiments of the present disclosure. At 542, the method 540 includes applying a positive voltage to a word line in a set of word lines. In some embodiments, the phase driver can be used to direct a voltage to a word line to activate the word line. That is, a phase driver may direct voltage to one word line in each set of word lines. That is, each phase driver is coupled to a sub word-line drivers associated with the first set of word lines and the second set of word lines. The phase driver coupled to the sub word-line driver associated with the word line that is to be activated will direct a positive voltage from a word line driver to the word line for activation. In some embodiments, other word lines (e.g., word lines unselected word lines) associated with the phase driver may receive a negative voltage provide by another word line driver. Further, the unintended activation of unselected word lines can be mitigated by using resistors. That is, when unselected word lines adjacent the activated word line increase in voltage, the resistors can counter act the increase in voltage of the unselected word line by decreasing the voltage.

In some embodiments, the sub word-line driver circuit may include a first word line driver and a second word line driver. The first word line driver may be coupled to the first set of word lines and the second word line driver may be coupled to the second set of word lines. That is, each word line driver may be coupled to a respective set of word lines. A word line driver coupled to a set of word lines will be coupled to all the word lines in the set of word lines. For instance, as illustrated in FIG. 2, each word line in the first set of word lines is coupled to the first word line driver. Similarly, as illustrated in FIG. 2, each word line in the second set of word lines is coupled to the second word line driver. Each word line driver can activate one of the plurality of word lines coupled to the word line driver. For example, the second word line driver may be used to activate the seventh word line in the second set of word line. That is, the second word line driver can apply a positive voltage to the seventh word line in the second set of word lines to activate the seventh word line.

At 543, the method 540 includes using one or more resistors attached to each word line of the first set of word lines and the second set of word lines to adjust the voltage received by one or more word lines in the first set of word lines and/or the second set of word lines. In some embodiments, the resistors may bias down voltage sent to word lines unintentionally. For example, to activate a particular word line, the phase driver may direct a voltage to a specified word line. In some cases, other word lines (e.g., other than the particular word line being activated) not associated with the active phase driver may receive voltage from word line/word line coupling and word line/digit line coupling. The resistors may bias down the voltage received by other word lines that are not being activated. That is, the resistors may cause the voltage received by the other non-activated word line to be a negative voltage. For example, the third phase driver is coupled to both the third word line in the first set of word lines and the seventh word line in the second set of word lines. When the word line driver activates the seventh word line, the phase driver may direct a positive voltage to the seventh word line and a negative voltage to the third word line. The resistors coupled to the word lines will bias the voltage received by the unselected word lines to prevent coupling.

That is, the resistor may bias down all word lines that are not intended to be activated. In some embodiments, all resistors coupled to each word line may bias down the word line attached to the resistor. The word lines not intended to be activated may receive a lower voltage, as compared to unbiased word lines. However, in this example, there is also a resistor attached to the word line intended for activation. The activated word line may use the received voltage to overcome the resistor and maintain a voltage of at least 3 volts.

At 544, the method 540 includes floating all word lines in the first set of word lines and the second set of word lines not associated with the activated phase driver. In some embodiments, the word lines associated with the non-active phase drivers will be temporarily floated. That is, the unselected word lines will be disconnected from the word line driver, via the sub word-line driver, temporarily to prevent coupling and unintentional activation. The unselected word lines may be floated while the specified word line is activated. In some embodiments, the unselected word lines will be floated from 1 microsecond to 100 microseconds.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

The figures herein follow a numbering convention in which the first digit or digits correspond to the drawing figure number and the remaining digits identify an element or component in the drawing. Similar (e.g., the same) elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” another element, the particular element can cover the other element, can be over the other element or lateral to the other element and/or can be in direct physical contact the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. An apparatus, comprising:
sets of word lines, each word line of the sets of word lines configured to access a respective set of one or more memory cells;
sets of digit lines; wherein each word line couples a memory cell of the set of one or more memory cells with each digit line within the sets of digit lines; and
a plurality of resistors coupled to the sets of word lines.

2. The apparatus of claim 1, wherein each resistor has a resistance in a range from 100 megaohms (MΩ) to 1 gigaohm (GΩ).

3. The apparatus of claim 1, wherein the sets of word lines further comprising vertically stacked sets of word lines.

4. The apparatus of claim 1, further comprising a plurality of phase drivers associated with each set of word lines.

5. The apparatus of claim 4, wherein the set of word lines is a first set of word lines and a second set of word lines, and further comprising a phase driver associated with a word line from the first set of word lines and another word line in the second set of word lines.

6. The apparatus of claim 3, further comprising a plurality of word line drivers, wherein each set of word lines is coupled to a word line driver though a sub word-line driver.

7. The apparatus of claim 1, wherein each word line in the set of word lines is coupled to a resistor of the plurality of resistors.

8. The apparatus of claim 1, wherein each digit line in the sets of digit lines is coupled to each word line in the sets of word lines.

9. A sub word-line driver circuit, comprising:
a first set of word lines arranged in a vertical stack, each word line of the first set of word lines configured to access a respective set of one or more memory cells;
a second set of word lines, communicatively coupled to the first set of word lines, each word line of the second set of word lines configured to access the respective set of one or more memory cells;
a first set of digit lines, wherein each word line of the first set of word lines couples a memory cell of the set of one or more memory cells with each digit line in the first set of digit lines;
a second set of digit lines, wherein each word line of the second set of word lines couples the memory cell of the set of one or more memory cells with each digit line in the second set of digit lines, and
wherein the second set of digit lines are electrically disconnected from the first set of digit lines.

10. The sub word-line driver circuit of claim 9, further comprising a plurality of phase drivers associated with the first set of word lines and the second set of word lines.

11. The sub word-line driver circuit of claim 10, comprising a first phase driver of the plurality of phase drivers associated with the first set of word lines.

12. The sub word-line driver circuit of claim 11, wherein the first phase driver is disconnected to the second set of word lines.

13. The sub word-line driver circuit of claim 12, comprising a second phase driver of the plurality of phase drivers associated with the second set of word lines.

14. The sub word-line driver circuit of claim 13, wherein the second phase driver is disconnected to the first set of word lines.

15. The sub word-line driver circuit of claim 9, further comprising a plurality of word line drivers coupled to the first set of word lines and the second set of word lines.

16. The sub word-line driver circuit of claim 15, wherein each word line driver is coupled to a word line in the first set of word lines and a word line in the second set of word lines.

17. The sub word-line driver circuit of claim 9, wherein the first set of digit lines is disconnected from the second set of word lines and the second set of digit lines is disconnected from the first set of word lines.

18. A method for activating a sub word-line driver circuit, comprising:
applying a positive voltage to a word line in a second set of word lines, wherein the second set of word lines are coupled to a second set of digit lines and the second set of digit lines are electrically disconnected from a first set of digit lines;
floating all word lines in a first set of word lines, wherein the first set of word lines are coupled to the first set of digit lines; and
applying a negative voltage to all unselected word lines in the second set of word lines.

19. The method of claim 18, comprising using a second phase driver to direct the positive voltage to the word line in the second set of word lines, wherein a first phase driver is coupled to the first set of word lines and the second phase driver is coupled to the second set of word lines.

20. The method of claim 19, comprising using a third word line driver to apply the positive voltage to the word line in the second set of word lines, wherein a first word line driver, a second word line driver, the third word line driver, and a fourth word line driver are coupled to the first set of word lines and the second set of word lines.
